(19) United States
(12) Patent Application Publication
(10) Pub. No.: US 2015/0076605 A1
(43) Pub. Date: Mar. 19, 2015

(54) Switching Device with Free-Wheeling Diode

(71) Applicant: Shanghai Baicheng Electric Equipment Manufacture Co., Ltd., Shanghai (CN)

(72) Inventor: Yingjie Cai, Shanghai (CN)

(21) Appl. No.: 13/995,019

(22) PCT Filed: Jun. 29, 2012
(86) PCT No.: PCT/CN12/77970

§ 371 Date: Jun. 17, 2013

(30) Foreign Application Priority Data
May 18, 2012 (CN) 201210162513.3

(51) Int. Cl. H01L 23/40; H01L 23/367; H01L 27/02; H01L 27/06

(52) U.S. Cl. CPC H01L 23/4006; H01L 27/0629; H01L 23/367; H01L 27/0255; H01L 27/0211; H01L 2023/4031; H01L 2023/405; H01L 2023/4081; H01L 2023/4087
USPC 257/355

(57) ABSTRACT

The disclosure provides a switching device with a free-wheeling diode, including a switching tube; a heat radiating substrate is arranged on the drain electrode of the switching tube; the switching device further includes a heat radiating component, which is connected with the heat radiating substrate of the switching tube by contact; the free-wheeling diode is a compression joint type diode; the anode end face of the free-wheeling diode is abutted against the heat radiating component, and is electrically connected with the drain electrode of the switching tube via the heat radiating component, which not only realizes the heat radiation function by using the heat radiating component, but also realizes the electric connection to the heat radiating substrate by using the electrical conductivity of the heat radiating component.

### FIELD OF THE INVENTION

The disclosure relates to the field of semiconductor, and in particular to a switching device with a free-wheeling diode.

### BACKGROUND OF THE INVENTION

At present, free-wheeling diodes are arranged in all the direct-current speed-regulating semiconductor switching devices, for providing the inductive load such as a motor with discharge channels at the instant of shutting down a switching device. FIG. 1 shows a circuit diagram of a semiconductor switching device with a free-wheeling diode, as shown in FIG. 1, the cathode of a free-wheeling diode 12 should be connected to the positive input of a power supply 11, the anode of the free-wheeling diode 12 is connected with a switching device 13, namely, the free-wheeling diode 12 is connected to two ends of a inductive load 14 in parallel, for providing a discharge loop for the current of the inductive load 14 when the switching device 13 is shut down. As the switching device and the free-wheeling diode 12 can continuously radiate heat when normally working, if overheating condition occurs, the working performance of the device may be affected, the working life of the device may be reduced, and even the fault of burning the device may occur when getting more serious; thereby, the normal work of the circuit is directly affected by the heat radiation of the free-wheeling diode 12.

In consideration of the heat radiation performance and capacity of the switching device, Transistor Outline (TO) packaged switching devices are generally used at present; FIG. 2 shows a diagram of a switching tube used for a switching device in the prior art; as shown in FIG. 2, a heat radiating substrate 131 is connected to a drain electrode 134 of a switching tube 13, a grid electrode 133 and a source electrode 135 are respectively located on both ends of the drain electrode 134; a semiconductor silicon wafer 132 is located on one side of the heat radiating substrate 131, and forms a step shape with the heat radiating substrate 131. The switching tube 13 implements heat radiation by enlarging the area of the heat radiating substrate.

However, the above switching tube 13 only considers the heat radiation performance of the switching device 13; the free-wheeling diode 12 is connected with the drain electrode 134 of the switching tube 13 via a welding mode, and is relatively far away from a heat radiating device; in addition, because of diodes with pins and soldering process, the cost is higher; the heat radiation effect is poor as the diode which is taken as one of heating sources is far away from the radiating device. Additionally, the technology of adopting soldering or butt-welding process to implement connection is relatively complex, and is easy to cause virtual welding and leakage welding; the assembling and disassembling operations are complex.

No effective solution has been put forward at present aiming at the problem that the free-wheeling diodes in the prior art have poor heat radiation effect.

### SUMMARY OF THE INVENTION

The main purpose of the disclosure is to provide a switching device with a free-wheeling diode to solve the problem that the free-wheeling diodes in the prior art have poor heat radiation effect.

In order to achieve the above purpose, the disclosure provides a switching device with a free-wheeling diode according to one aspect.

The switching device with a free-wheeling diode provided by the disclosure includes a switching tube; a heat radiating substrate is arranged on the drain electrode of the switching tube; the switching device with the free-wheeling diode further includes a heat radiating component, which is connected with the heat radiating substrate of the switching tube by contact; the free-wheeling diode is a compression joint type diode, the anode end face of the free-wheeling diode is abutted against the heat radiating component, and is electrically connected with the drain electrode of the switching tube via the heat radiating component.

Further, the switching device with the free-wheeling diode provided by the disclosure further includes a positive power supply input component, which is arranged between the cathode end face of the free-wheeling diode and the anode of a power supply.

Further, the switching device with the free-wheeling diode provided by the disclosure further includes an elastic component, which is arranged between the positive power supply input component and the free-wheeling diode, and by which the free-wheeling diode is elastically pressed between the positive power supply input component and the heat radiating component.

Further, the elastic component comprises an elastic plate which is convex towards the first side of the elastic component; the first side is opposite to the cathode end face of the free-wheeling diode, and the elastic plate is abutted against the cathode end face of the free-wheeling diode.

Further, the elastic plate is located in the middle of the elastic component.

Further, the elastic component comprises two hooks which are bent towards the second side of the elastic component; the second side is opposite to the positive power supply input component, two fixed slots are arranged on the positive power supply input component; the hooks are embedded into the fixed slots, so that the elastic component is fixed on the positive power supply input component.

Further, the hooks are located on both ends of the elastic component.

Further, a convex edge for clamping is arranged on one side of the elastic component.

Further, the heat radiating component includes a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

Further, the first cooling fin, the second cooling fin and the heat radiating substrate are fixed together via a plurality of screws.

According to the technical solution of the disclosure, a switching device with a free-wheeling diode includes a switching tube; the drain electrode of the switching tube is provided with a heat radiating substrate; the switching device further includes a radiating component, which is connected with the heat radiating substrate of the switching tube by contact; the free-wheeling diode is a compression joint type diode; the anode end face of the free-wheeling diode is abutted against the heat radiating component, and is electrically connected with the drain electrode of the switching tube via the heat radiating component, which not only realizes the heat radiation function by using the heat radiating component, but also realizes the electric connection with the heat radiating substrate by using the electric conductivity of the heat radiating component.

### BRIEF DESCRIPTION OF THE DRAWINGS

The drawings of the specifications are used for further understanding the disclosure, and forming a part of the application; the schematic embodiments of the disclosure and the specifications thereof are used for explaining the disclosure, without forming improper limit to the disclosure. In the drawings:

FIG. 1 shows a circuit diagram of a semiconductor switching device with a free-wheeling diode;

FIG. 2 shows a diagram of a switching tube used for a switching device in the prior art;

FIG. 3 shows a diagram of a switching device with a free-wheeling diode according to an embodiment 1 of the disclosure;

FIG. 4 shows a diagram of a switching device with a free-wheeling diode according to an embodiment 2 of the disclosure;

FIG. 5 shows a diagram of an elastic component of the switching device with the free-wheeling diode according to the embodiment 2 of the disclosure; and

FIG. 6 shows a diagram of a switching device with a free-wheeling diode according to an embodiment 3 of the disclosure.

### DETAILED DESCRIPTION OF THE EMBODIMENTS

It should note that, the embodiments in the application and the characteristics of the embodiments can be mutually combined without conflict. The disclosure is described below in details with reference to the drawings and embodiments.

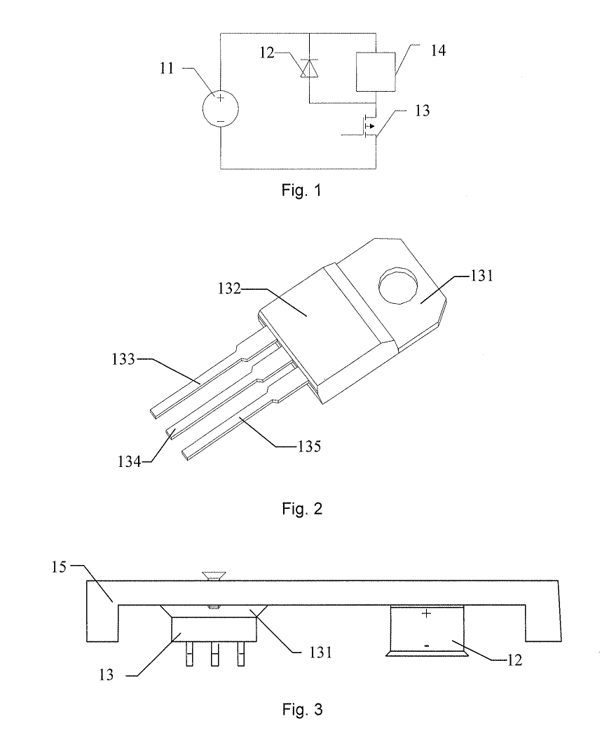

The circuit connection relationship adopted by the switching device with the free-wheeling diode in the embodiment of the disclosure is consistent with the circuit diagram of FIG. 1; the circuit connection is not modified, and the adopted switching tube is a TO-packaged switching tube, such as a Metal Oxide Semiconductor Field Effect Transistor (MOSFET). The drain electrode of the MOSFET is electrically connected with the heat radiating substrate. The free-wheeling diode 12 adopted in the embodiment of the disclosure is a compression joint type diode; the anode end face of the compression joint type diode is directly abutted against on the heat radiating component 15; the cooling fins are generally metal materials; thereby, the disclosure not only uses the heat radiating component 15 to implement heat radiation, but also uses the electric conductivity of the heat radiating component 15 to realize electric connection with the heat radiating substrate 131.

FIG. 3 shows a diagram of a switching device with a free-wheeling diode according to an embodiment 1 of the disclosure; as shown in FIG. 3, the switching device in the embodiment 1 includes a heat radiating component 15, which is connected with the heat radiating substrate 131 of the switching tube; the anode end face of the free-wheeling diode 12 is abutted against the heat radiating component 15, and is electrically connected with the drain electrode of the switching tube 13 via the heat radiating component 15. Via the connection mode, one end face of the free-wheeling diode 12 tightly abuts against the heat radiating component 15, which can effectively use the heat radiating component 15 to implement heat radiation, and can use the electric conductivity of the heat radiating component 15 to realize the electric connection with the heat radiating substrate 131.

As the heat radiating substrate 131 of the switching tube is generally provided with through holes, the heat radiating substrate 131 and the heat radiating component 15 can be contacted via the screw fixing mode. Except the screw fixing mode, the adhesion, compression joint, welding modes and the like also can be suitable.

There can be various abutting modes between the anode end face of the free-wheeling diode 12 and the heat radiating component 15, the free-wheeling diode can be adhered on the heat radiating component 15 by using heat conduction silica gel, and also the anode end face of the free-wheeling diode 12 can be tightly pressed on the heat radiating component 15 by exerting a certain pressure on the cathode end of the free-wheeling diode 12; or the anode end face of the free-wheeling diode 12 is adhered on the heat radiating component 15 by using the similar paster technology in the electronic welding technologies; in consideration of the electrical connection relationship of the free-wheeling diode 12, the free-wheeling diode 12 can be considerably pressed to the heat radiating component 15 by using the input component 17 of a power supply.

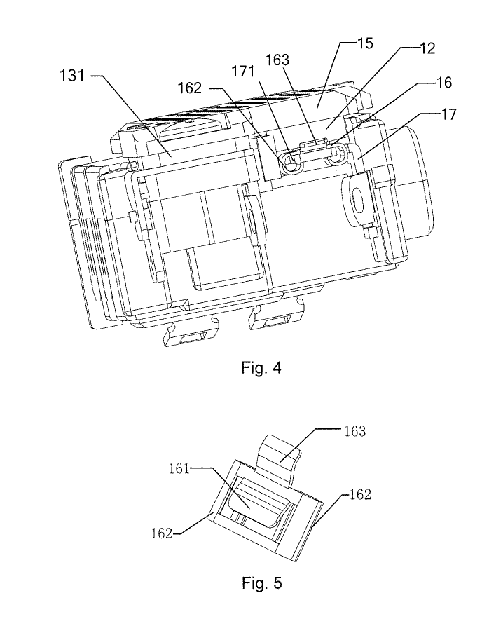

Based on the above considerations, the embodiment 1 is modified by the embodiment 2 of the disclosure; FIG. 4 shows a diagram of a switching device with a free-wheeling diode according to the embodiment 2 of the disclosure; as shown in FIG. 4, the switching device with the free-wheeling diode of the embodiment 2 of the disclosure further includes a positive power supply input component 17, which is arranged between the cathode end face of the free-wheeling diode 12 and the anode of the power supply. The positive power supply input component 17 not only realizes the electric connection relationship between the cathode end face of the free-wheeling diode 12 and the power supply, but also tightly clamp the free-wheeling diode 12 between the heat radiating component 15 and the positive power supply input component 17 by setting the interval between the positive power supply input component 17 and the heat radiating component 15.

Via the compression joint mode, the free-wheeling diode 12 can be fixed without using the soldering or butt-welding modes, thus avoiding the unreliability and complex assembly caused by the complex technologies.

However, the interval matching problem is caused by directly using two rigid components to clamp; following the changes of environments, the deformation is caused to make the clamping unreliable, therefore, an elastic component 16 is also arranged in the embodiment 2; the elastic component 16 is arranged between the positive power supply input component 17 and the free-wheeling diode 12, and presses the free-wheeling diode 12 between the positive power supply input component 17 and the heat radiating component 15 by using the elasticity. The diode is fixed by adopting the elasticity and rigidity combination mode, so as to improve the compression joint reliability.

FIG. 5 shows a diagram of an elastic component of the switching device with the free-wheeling diode according to the embodiment 2 of the disclosure, as shown in FIG. 5, the elastic component 16 includes an elastic plate 161 which is convex towards the first side of the elastic component; the first side is opposite to the cathode end face of the free-wheeling diode 12; the elastic plate 161 is abutted against the cathode end face of the free-wheeling diode 12. After assembling, the elastic plate 161 is deformed, and the free-wheeling diode 12 is pressed to the heat radiating component 15 by using the elasticity generated by the deformation. The second side at the back of the first side is fixed on the positive power supply input component 17; the elastic component 16 can be made of materials with excellent conductivity, thus achieving the electric connection relationship with the cathode of the free-wheeling diode 12.

In order to guarantee the uniformity of elasticity and the convenience of the assembly and processing, the elastic plate 161 is preferably arranged in the middle of the elastic component 16.

There are various fixing modes between the elastic component 16 and the positive power supply input component 17, such as compression joint, welding, adhesion and the like; the embodiment 2 of the disclosure preferably adopts a fixing mode of embedding the elastic component 16 into the positive power supply input component 17. Two hooks 162 which are bent towards the second side are arranged by the elastic component 16, the second side is opposite to the positive power supply input component 17, two fixed slots 171 are opened on the positive power supply input component 17; the hooks 162 are embedded into the fixed slots 171, so that the elastic component 16 is fixed on the positive power supply input component 17. Wherein, the two hooks 162 are preferably arranged on both ends of the elastic component 16.

The elastic component 16 is fixed on the positive power supply input component 17 by adopting the above fixing modes; the assembly modes are simple and highly-reliable, without using extra materials; thus the cost is saved.

After pressing the elastic component 16 between the free-wheeling diode 12 and the positive power supply input component 17, a necessary convex part for clamping is lack when disassembling; therefore, one side of the elastic component 16 also can be provided with a convex edge 163 for clamping; after assembling, the convex edge 163 is located outside the free-wheeling diode 12, and can be conveniently disassembled and assembled. In addition, the convex edge 163 limits the movement of the free-wheeling diode 12 along the extension location of the elastic plate 161, so that the free-wheeling diode 12 can be reliably fixed between the elastic component 16 and the heat radiating component 15.

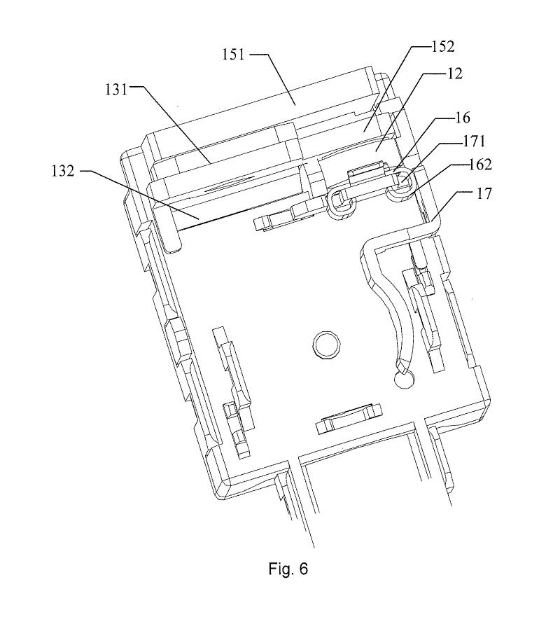

The free-wheeling diode 12 and the switching tube use the same heat radiating component 15 in the embodiment 2; in order to achieve better heat radiation performance, the embodiment 2 is modified by the embodiment 3 of the disclosure; FIG. 6 shows a diagram of the switching device with the free-wheeling diode according to the embodiment 3 of the disclosure; as shown in FIG. 6, the heat radiating component 15 includes a first cooling fin 151 and a second cooling fin 152; the heat radiating substrate 131 is clamped in the middle by the first cooling fin 151 and the second cooling fin 152, wherein the second cooling fin 152 is located on one side of the semiconductor silicon wafer 132 of the switching tube 13, and is arranged on the step formed between the semiconductor silicon wafer 132 of the switching tube and the heat radiating substrate 131; the anode of the free-wheeling diode 12 abuts against the second heat radiating component 152. And the other parts are fully consistent with the connection relationship of the embodiment 2.

As the heat of the switching tube is mainly radiated by the semiconductor silicon wafer 132, and the contact area of the first cooling fin 151 and the semiconductor silicon wafer 132 is larger, the heat radiation of the switching tube is mainly realized by the first cooling fin 151, and the second cooling fin 152 is mainly configured to implement heat radiation for the free-wheeling diode 12, thus further improving the heat radiation effect of the free-wheeling diode. In addition, a heat radiation loop is formed between the first cooling fin 151 and the second cooling fin 152, thus obtaining larger heat radiation area and volume and better heat radiation effect.

There are various connection modes among the first cooling fin 151, the second cooling fin 152 and the heat radiating substrate 131, preferably, they are fixed by a plurality of screws.

All the free-wheeling diodes 12 in the above embodiments can adopt the button type diodes. The price of such diodes can be cheaper than the axially-packaged diodes with pins.

According to the technical solution of the disclosure, a switching device with a free-wheeling diode includes a switching tube; the drain electrode of the switching tube is provided with a heat radiating substrate; the switching device further includes: a radiating component, which is connected with the heat radiating substrate of the switching tube by contact; the free-wheeling diode is a compression joint type diode; the anode end face of the free-wheeling diode is abutted against the heat radiating component, and is electrically connected with the drain electrode of the switching tube via the heat radiating component, which not only realizes the heat radiation function by using the heat radiating component, but also realizes the electric connection with the heat radiating substrate by using the electric conductivity of the heat radiating component.

The above is only the preferred embodiment of the disclosure and not intended to limit the disclosure, and for those skilled in the art, the disclosure can have various modifications and changes. Any modifications, equivalent replacements, improvements and the like within the spirit and principle of the disclosure shall fall within the scope of protection of the disclosure.

1. A switching device with a free-wheeling diode, the switching device comprising a switching tube, with a heat radiating substrate being arranged on the drain electrode of the switching tube, wherein, the switching device further comprises:
a heat radiating component, which is connected with the heat radiating substrate of the switching tube by contact;
wherein, the free-wheeling diode is a compression joint type diode, the anode end face of the free-wheeling diode is abutted against the heat radiating component, and is electrically connected with the drain electrode of the switching tube via the heat radiating component.

2. The switching device according to claim 1, wherein further comprising a positive power supply input component, which is arranged between the cathode end face of the free-wheeling diode and the anode of a power supply.

3. The switching device according to claim 2, wherein further comprising an elastic component, which is arranged between the positive power supply input component and the free-wheeling diode, and by which the free-wheeling diode is elastically pressed between the positive power supply input component and the heat radiating component.

4. The switching device according to claim 3, wherein, the elastic component comprises an elastic plate which is convex towards the first side of the elastic component; the first side is opposite to the cathode end face of the free-wheeling diode, and the elastic plate is abutted against the cathode end face of the free-wheeling diode.

5. The switching device according to claim 4, wherein the elastic plate is located in the middle of the elastic component.

6. The switching device according to claim 3, wherein the elastic component comprises two hooks which are bent towards the second side of the elastic component; the second side is opposite to the positive power supply input component, two fixed slots are arranged on the positive power supply input component; the hooks are embedded into the fixed slots, so that the elastic component is fixed on the positive power supply input component.

7. The switching device according to claim 6, wherein the hooks are located on both ends of the elastic component.

8. The switching device according to claim 3, wherein a convex edge for clamping is arranged on one side of the elastic component.

9. The switching device according to claim 1, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

10. The switching device according to claim 9, wherein the first cooling fin, the second cooling fin and the heat radiating substrate are fixed together via a plurality of screws.

11. The switching device according to claim 4, wherein a convex edge for clamping is arranged on one side of the elastic component.

12. The switching device according to claim 6, wherein a convex edge for clamping is arranged on one side of the elastic component.

13. The switching device according to claim 7, wherein a convex edge for clamping is arranged on one side of the elastic component.

14. The switching device according to claim 2, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

15. The switching device according to claim 3, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

16. The switching device according to claim 4, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

17. The switching device according to claim 5, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

18. The switching device according to claim 6, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.

19. The switching device according to claim 7, wherein, the heat radiating component comprises a first cooling fin and a second cooling fin; the heat radiating substrate is clamped between the first cooling fin and the second cooling fin; wherein the second cooling fin is located on one side of a semiconductor silicon wafer of the switching tube, and is arranged on a step formed between the semiconductor silicon wafer and the heat radiating substrate of the switching tube, the anode end face of the free-wheeling diode is abutted against the second cooling fin.
